(19) United States
(12) Patent Application Publication
(10) Pub. No.: US 2026/0304623 A1
(43) Pub. Date: Oct. 1, 2026

(54) CIRCUIT STRUCTURE AND MANUFACTURING METHOD THEREOF

(71) Applicant: SILICONWARE PRECISION INDUSTRIES CO., LTD., Taichung City (TW)

(72) Inventors: Pao-Hung TSENG, Taichung City (TW); Yu-Cheng PAI, Taichung City (TW); Hung-Kun CHEN, Taichung City (TW); Yuan-Ping YEH, Taichung City (TW)

(73) Assignee: SILICONWARE PRECISION INDUSTRIES CO., LTD., Taichung City (TW)

(21) Appl. No.: 19/330,488

(22) Filed: Sep. 16, 2025

(30) Foreign Application Priority Data
Mar. 27, 2025 (TW) 114111818

(51) Int. Cl. H05K 1/11; H05K 3/00

(52) U.S. Cl. CPC H05K 1/116; H05K 3/0026; H05K 2201/0367; H05K 2201/09527; H05K 2201/096

(57) ABSTRACT

Provided are a circuit structure and a method of manufacturing the circuit structure. A first circuit layer and first conductive blind vias are formed on a first dielectric material. Conductive bumps are formed on the first conductive blind vias. Then, a second dielectric material is formed on the first circuit layer, and a second circuit layer and second conductive blind vias are formed on the second dielectric material. The second conductive blind vias are stacked on the first conductive blind vias, and the conductive bumps are formed at junctions between the first conductive blind vias and the second conductive blind vias to increase the contact area between the first conductive blind vias and the second conductive blind vias.

### BACKGROUND

### 1. Technical Field

The present disclosure relates to a semiconductor structure, and more particularly, to a circuit structure and a manufacturing method thereof.

### 2. Description of Related Art

With the vigorous development of the electronics industry, electronic products tend to be thinner, lighter, shorter, and smaller in shape, and the functions are developing towards high performance, high functionality, and high speed. Therefore, in order to meet the requirements of high integration and miniaturization of semiconductor devices, package substrates with thinner, low warpage, and high-density wiring designs are often used in the packaging process.

FIG. 1A to FIG. 1D are schematic cross-sectional views illustrating a conventional method for manufacturing a package substrate.

As shown in FIG. 1A, a core layer 10 is provided, and a conductive via 100 is formed in the core layer 10.

As shown in FIG. 1B, a copper foil dielectric material 11 is laminated on each of two opposite sides of the core layer 10.

As shown in FIG. 1C, a first blind hole 110 is formed in the copper foil dielectric material 11. Chemical copper 12 is then deposited thereon and a copper electroplating process is performed to form a first circuit layer 13 on the copper foil dielectric material 11 and to form a first conductive blind via 130 in the first blind hole 110.

As shown in FIG. 1D, another copper foil dielectric material 14 is laminated on the first circuit layer 13, and a second blind hole 140 is formed in the another copper foil dielectric material 14. Chemical copper is subsequently deposited and a copper electroplating process is performed to form a second circuit layer 15 on the first circuit layer 13 and to form a second conductive blind via 150 in the second blind hole 140.

However, in modern electronic products, the need to improve wiring density for faster signal transmission requires that the diameters of the conductive blind vias be reduced and that stacked (superposed) vias be employed. In current designs, the interface of the stacked vias forms a 2D layer of electroplated copper-chemical copper-electroplated copper. When stress is present, this 2D interface is susceptible to cracking at the bottom of the conductive blind via.

Therefore, there is a need for a solution that addresses the aforementioned shortcomings of the prior art.

### SUMMARY

In view of the aforementioned shortcomings of the prior art, the present disclosure provides a circuit structure, which comprises: a first dielectric material; a first circuit layer formed on the first dielectric material; a plurality of first conductive blind vias formed in the first dielectric material and connected to the first circuit layer; a second dielectric material formed on the first circuit layer; a second circuit layer formed on the second dielectric material; a plurality of second conductive blind vias formed in the second dielectric material and connected to the second circuit layer, each of the plurality of second conductive blind vias being stacked on a corresponding one of the plurality of first conductive blind vias; and a plurality of conductive bumps, each being formed at a junction between a respective one of the plurality of first conductive blind vias and a corresponding one of the plurality of second conductive blind vias.

The present disclosure further provides a method of manufacturing a circuit structure, and the method comprises: forming a first circuit layer on a first dielectric material, and forming a plurality of first conductive blind vias connected to the first circuit layer in the first dielectric material; forming a conductive bump on each of the plurality of first conductive blind vias; forming a second dielectric material on the first circuit layer; and forming a second circuit layer on the second dielectric material, and forming a plurality of second conductive blind vias connected to the second circuit layer in the second dielectric material, wherein each of the plurality of second conductive blind vias is stacked on a corresponding one of the plurality of first conductive blind vias, and each of the conductive bumps is formed at a junction between a respective one of the plurality of first conductive blind vias and a corresponding one of the plurality of second conductive blind vias.

In the aforementioned circuit structure and method, the present disclosure further comprises: providing a substrate for disposing the first dielectric material.

In the aforementioned circuit structure and method, the substrate is an insulating layer, a wiring layer, a carrier board, or a core board.

In the aforementioned circuit structure and method, the core board is formed with a plurality of conductive vias therein, and each of the plurality of first conductive blind vias is stacked on a corresponding one of the plurality of conductive vias.

In the aforementioned circuit structure and method, the present disclosure further comprises: forming another conductive bump interposed between each of the plurality of conductive vias and a corresponding one of the plurality of first conductive blind vias.

In the aforementioned circuit structure and method, a height of each of the conductive bumps is at least 5 micrometers.

In the aforementioned circuit structure and method, the second dielectric material is formed with a plurality of second blind holes, and each of the plurality of second conductive blind vias is formed in a corresponding one of the plurality of second blind holes.

In the aforementioned circuit structure and method, a planar dimension of each of the conductive bumps is 0.3 to 0.5 times a bottom hole diameter of a corresponding one of the plurality of second blind holes.

As can be understood from the above, in the circuit structure and manufacturing method thereof according to the present disclosure, the contact area between the first conductive blind via and the second conductive blind via (and the first conductive blind via and the conductive via) is increased by disposing the conductive bump at the junction between the first conductive blind via and the second conductive blind via (and the first conductive blind via and the conductive via), thereby preventing crack formation at the stacked interface due to stress.

### BRIEF DESCRIPTION OF THE DRAWINGS

FIG. 1A to FIG. 1D are schematic cross-sectional views illustrating a conventional method for manufacturing a package substrate.

FIG. 2A to FIG. 2E are schematic cross-sectional views illustrating a method for manufacturing a circuit structure according to the present disclosure.

FIG. 3 is a schematic cross-sectional view of a circuit structure according to another embodiment of the present disclosure.

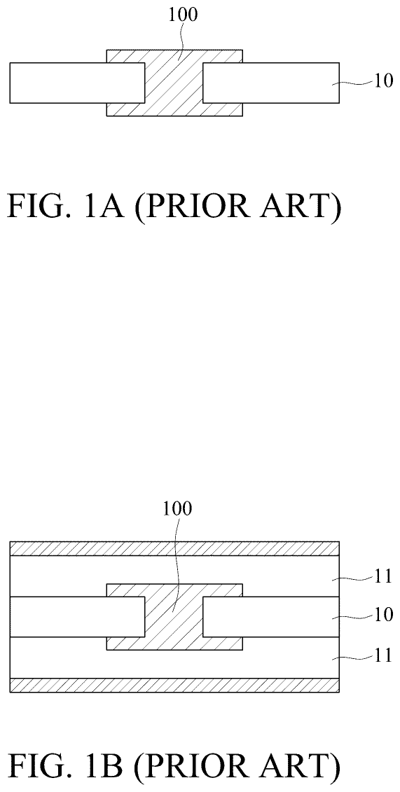

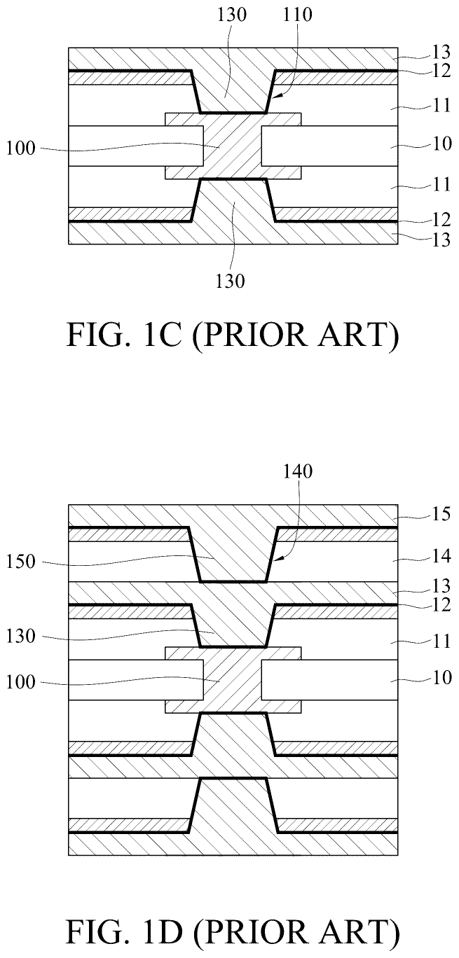

### DETAILED DESCRIPTION

Embodiments of the present disclosure are described below by examples. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes, or adjustments to the structures, ratios, or sizes are construed as falling within the scope covered by the technical contents disclosed herein. Meanwhile, terms such as “on,” “above,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

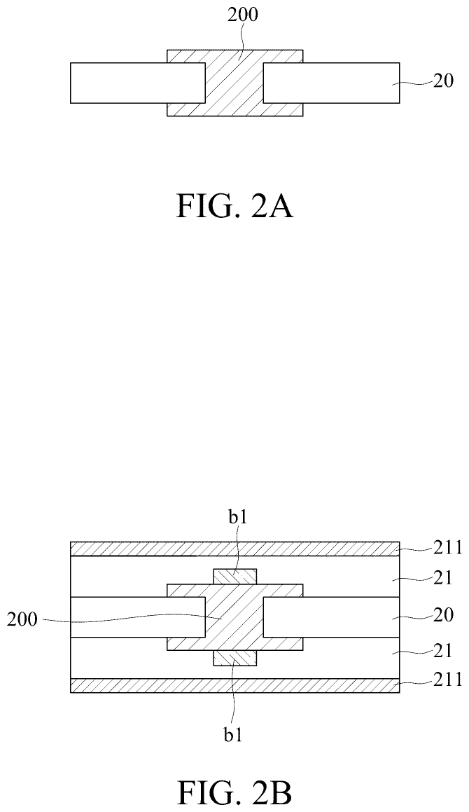

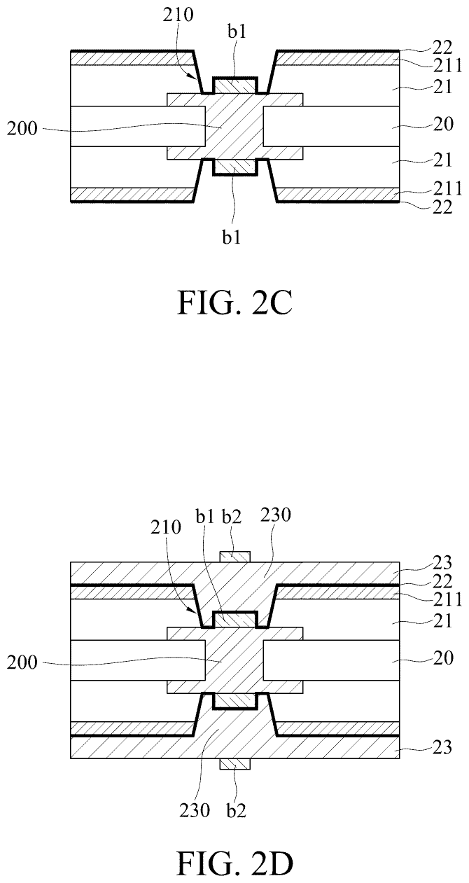

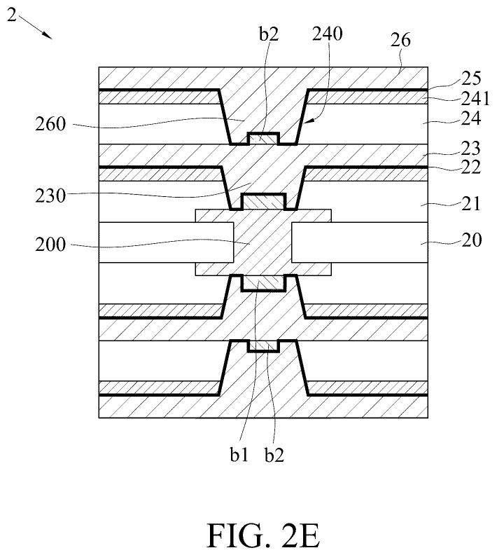

FIG. 2A to FIG. 2E are schematic cross-sectional views illustrating a method for manufacturing a circuit structure 2 according to the present disclosure.

As shown in FIG. 2A, a substrate or a substrate material is provided. In one embodiment, the substrate is a core board 20 (which includes a core layer and copper foils disposed on both sides), and a plurality of conductive vias 200 penetrating through the core layer are formed in the core board 20 (for ease of illustration, only one conductive via 200 is shown). In other embodiments, the substrate may also be an insulating layer, a wiring layer, or a carrier board.

As shown in FIG. 2B, a first conductive bump b1 is formed by electroplating at each of two opposite ends of the conductive via 200, and then a first dielectric material 21 having a first metal layer 211 is laminated on each of two opposite sides of the core board 20, wherein planar dimensions of the first conductive bump b1 are smaller than planar dimensions of the end of the conductive via 200.

The first dielectric material 21 is, for example, prepreg (PP), polybenzoxazole (PBO), or polyimide (PI). The first metal layer 211 is, for example, copper foil.

As shown in FIG. 2C, at least one first blind hole 210 is formed on the first dielectric material 21 having the first metal layer 211, wherein the first blind hole 210 corresponds to a position of the conductive via 200, and the first conductive bump b1 is exposed from the first blind hole 210.

The first blind hole 210 can be formed by a laser drilling process and can have a conical or funnel-shaped structure as illustrated.

In one embodiment, the planar dimension (width) of the first conductive bump b1 is 0.3 to 0.5 times the bottom hole diameter of the first blind hole 210, and a height of the first conductive bump b1 is at least 5 micrometers (μm), but the present disclosure is not limited to as such.

Then, a conductive layer 22 is formed on the first dielectric material 21 having the first metal layer 211 and in the first blind hole 210 (including an outer surface of the first conductive bump b1). The conductive layer 22 is formed by depositing chemical copper.

As shown in FIG. 2D, a first wiring layering process (a build-up process) is performed so that, on both sides of the core board 20, a first circuit layer 23 and a first conductive blind via 230 are formed. In one embodiment, the first circuit layer 23 is formed on the first dielectric material 21 by an electroplating process, and the first conductive blind via 230 is formed in the first blind hole 210, wherein the first conductive blind via 230 is stacked above the corresponding conductive via 200, and the first conductive bump b1 is located at a junction between the first conductive blind via 230 and the conductive via 200. Then, a second conductive bump b2 is formed at an exposed end of the first conductive blind via 230, and planar dimensions of the second conductive bump b2 are smaller than planar dimensions of an end of the first conductive blind via 230.

The conductive layer 22 serves as a seed layer for electroplating copper material to form the first circuit layer 23.

As shown in FIG. 2E, a second wiring layering process (a build-up process) is performed. In a manner analogous to the foregoing process, a second dielectric material 24 having a second metal layer 241 is formed on the first circuit layer 23, a second blind hole 240 is formed, a conductive layer 25 is formed, and a second circuit layer 26 and a second conductive blind via 260 are formed by electroplating, wherein the second conductive blind via 260 is stacked above the corresponding first conductive blind via 230, and the second conductive bump b2 is interposed between the first conductive blind via 230 and the second conductive blind via 260, thus the circuit structure 2 of the present disclosure is formed, wherein the circuit structure 2 bonded with the core board 20 can be used as a package substrate for carrying chips.

In one embodiment, the planar dimension (width) of the second conductive bump b2 is 0.3 to 0.5 times a bottom hole diameter of the second blind hole 240. In addition, a height of the second conductive bump b2 is at least 5 micrometers (μm).

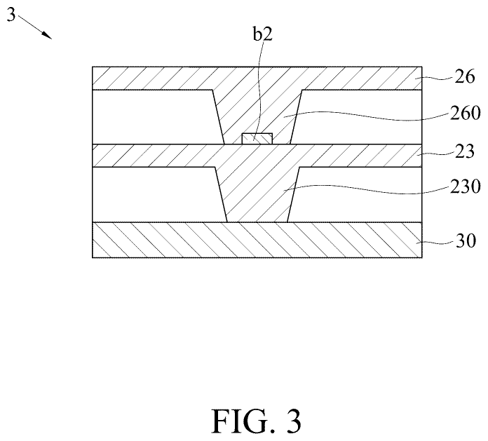

Reference is now made to FIG. 3, which shows a schematic cross-sectional view of a redistribution circuit structure 3 according to another embodiment of the present disclosure. This embodiment is substantially similar to the aforementioned embodiment; the main difference is that a substrate such as a wiring layer 30 is provided, and a first circuit layer 23 (with a first conductive blind via 230) and a second circuit layer 26 (with a second conductive blind via 260) are sequentially formed and stacked on the wiring layer 30, and a second conductive bump b2 is formed at a junction between the first conductive blind via 230 and the corresponding second conductive blind via 260 to form a multi-layer circuit structure.

Through the above-mentioned manufacturing method, the present disclosure further discloses a circuit structure 2, 3, which comprises: a first dielectric material 21; a first circuit layer 23 formed on the first dielectric material 21; a plurality of first conductive blind vias 230 formed in the first dielectric material 21 and connected to the first circuit layer 23; a second dielectric material 24 formed on the first circuit layer 23; a second circuit layer 26 formed on the second dielectric material 24; a plurality of second conductive blind vias 260 formed in the second dielectric material 24 and connected to the second circuit layer 26, with each of the second conductive blind vias 260 being stacked on its corresponding first conductive blind via 230; and a plurality of conductive bumps (second conductive bumps b2), each disposed at a junction between the first conductive blind via 230 and its corresponding second conductive blind via 260.

The circuit structure 2, 3 further includes a substrate for disposing the first dielectric material 21.

The substrate may be an insulating layer, a wiring layer 30, a carrier board, or a core board 20. In the core board 20, at least one or a plurality of conductive vias 200 are formed, with each of the first conductive blind vias 230 being stacked on its corresponding conductive via 200, and a conductive bump (first conductive bump b1) being interposed between the conductive via 200 and its corresponding first conductive blind via 230.

In view of the above, in the circuit structure and manufacturing method thereof according to the present disclosure, the contact area between the first conductive blind via and the second conductive blind via (and the first conductive blind via and the conductive via) is increased by disposing the conductive bump at the junction between the first conductive blind via and the second conductive blind via (and the first conductive blind via and the conductive via), thereby preventing crack formation at the stacked interface due to stress.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A circuit structure, comprising:
a first dielectric material;
a first circuit layer formed on the first dielectric material;
a plurality of first conductive blind vias formed in the first dielectric material and connected to the first circuit layer;
a second dielectric material formed on the first circuit layer;
a second circuit layer formed on the second dielectric material;
a plurality of second conductive blind vias formed in the second dielectric material and connected to the second circuit layer, each of the plurality of second conductive blind vias being stacked on a corresponding one of the plurality of first conductive blind vias; and
a plurality of conductive bumps, each being formed at a junction between a respective one of the plurality of first conductive blind vias and a corresponding one of the plurality of second conductive blind vias.

2. The circuit structure of claim 1, further comprising: a substrate for disposing the first dielectric material.

3. The circuit structure of claim 2, wherein the substrate is an insulating layer, a wiring layer, a carrier board, or a core board.

4. The circuit structure of claim 3, wherein the core board is formed with a plurality of conductive vias therein, and each of the plurality of first conductive blind vias is stacked on a corresponding one of the plurality of conductive vias.

5. The circuit structure of claim 4, further comprising: another conductive bump interposed between each of the plurality of conductive vias and a corresponding one of the plurality of first conductive blind vias.

6. The circuit structure of claim 1, wherein a height of each of the plurality of conductive bumps is at least 5 micrometers.

7. The circuit structure of claim 1, wherein the second dielectric material is formed with a plurality of second blind holes, and each of the plurality of second conductive blind vias is formed in a corresponding one of the plurality of second blind holes.

8. The circuit structure of claim 7, wherein a planar dimension of each of the plurality of conductive bumps is 0.3 to 0.5 times a bottom hole diameter of a corresponding one of the plurality of second blind holes.

9. A method of manufacturing a circuit structure, comprising:
forming a first circuit layer on a first dielectric material, and forming a plurality of first conductive blind vias connected to the first circuit layer in the first dielectric material;
forming a conductive bump on each of the plurality of first conductive blind vias;
forming a second dielectric material on the first circuit layer; and
forming a second circuit layer on the second dielectric material, and forming a plurality of second conductive blind vias connected to the second circuit layer in the second dielectric material, wherein each of the plurality of second conductive blind vias is stacked on a corresponding one of the plurality of first conductive blind vias, and each of the conductive bumps is formed at a junction between a respective one of the plurality of first conductive blind vias and a corresponding one of the plurality of second conductive blind vias.

10. The method of claim 9, further comprising: providing a substrate for disposing the first dielectric material.

11. The method of claim 10, wherein the substrate is an insulating layer, a wiring layer, a carrier board, or a core board.

12. The method of claim 11, wherein the core board is formed with a plurality of conductive vias therein, and each of the plurality of first conductive blind vias is stacked on a corresponding one of the plurality of conductive vias.

13. The method of claim 12, further comprising: forming another conductive bump interposed between each of the plurality of conductive vias and a corresponding one of the plurality of first conductive blind vias.

14. The method of claim 9, wherein a height of each of the conductive bumps is at least 5 micrometers.

15. The method of claim 9, wherein the second dielectric material is formed with a plurality of second blind holes, and each of the plurality of second conductive blind vias is formed in a corresponding one of the plurality of second blind holes.

16. The method of claim 15, wherein a planar dimension of each of the conductive bumps is 0.3 to 0.5 times a bottom hole diameter of a corresponding one of the plurality of second blind holes.
